(19) United States
(12) Patent Application Publication
(10) Pub. No.: US 2009/0074962 A1
(43) Pub. Date: Mar. 19, 2009

(54) Method for the protection of an optical element of a lithographic apparatus and device manufacturing method

(75) Inventors: Maarten Marinus Johannes Wilhelmus Van Herpen, Heesch (NL); Wouter Anthon Soer, Nijmegen (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/898,801

(22) Filed: Sep. 14, 2007

(51) Int. Cl. C23C 16/06

(52) U.S. Cl. 427/250; 118/722

(57) ABSTRACT

A method for the protection of an optical element of a lithographic apparatus is disclosed. A deposition gas comprising SnH₄ is provided to the surface of the optical element to deposit a Sn cap layer on the surface of the optical element. In this way, a Sn cap layer is deliberately provided on the optical element, which may protect the optical element during lithographic processing from debris from a (Sn) plasma source. During or after lithographic processing, the (deteriorated) cap layer may be repaired by providing a hydrogen radical containing gas and/or a SnH4 containing gas. Additionally or alternatively, the (deteriorated) cap layer may be removed and a new cap layer provided by providing the deposition gas comprising SnH₄.

### FIELD

The present invention relates to a method for the protection of an optical element of a lithographic apparatus and to a device manufacturing method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of one or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include steppers, in which each target portion is irradiated by exposing an entire pattern onto the target portion at one time, and scanners, in which each target portion is irradiated by scanning the pattern through a radiation beam in a given direction (the “scanning” direction) while synchronously scanning the substrate parallel or anti-parallel to this direction. It is also possible to transfer the pattern from the patterning device to the substrate by imprinting the pattern onto the substrate.

In a lithographic projection apparatus, the size of features that can be imaged onto the substrate is limited by the wavelength of the projection radiation. To produce integrated circuits with a higher density of devices, and hence higher operating speeds, it is desirable to be able to image smaller features. While most current lithographic projection apparatus employ ultraviolet light generated by mercury lamps or excimer lasers, it has been proposed to use shorter wavelength radiation, e.g. of around 13 nm. Such radiation is termed extreme ultraviolet (EUV) or soft x-ray, and possible sources include, for example, laser-produced plasma sources, discharge plasma sources, or synchrotron radiation from electron storage rings.

The source of EUV radiation is typically a plasma source, for example a laser-produced plasma or a discharge source. A common feature of any plasma source is the production of fast ions and atoms, which are expelled from the plasma in all directions. These particles can be damaging to the collector and condenser mirrors which are generally multilayer mirrors or grazing incidence mirrors, with fragile surfaces. This surface is gradually degraded due to the impact, or sputtering, of the particles expelled from the plasma and the lifetime of the mirrors is thus decreased. The sputtering effect is particularly problematic for the radiation collector or collector mirror. The purpose of the collector is to collect radiation which is emitted in all directions by the plasma source and direct it towards other mirrors in the illumination system. The radiation collector is positioned very close to, and in line-of-sight with, the source of EUV in the plasma source and therefore receives a large flux of fast particles from the plasma. Other mirrors in the system are generally damaged to a lesser degree by sputtering of particles expelled from the plasma since they may be shielded to some extent.

In the near future, extreme ultraviolet (EUV) sources will probably use tin (Sn) or another metal vapor to produce EUV radiation. This tin may be deposited on mirrors, e.g. a mirror of the radiation collector, and/or leak into the lithographic apparatus. A mirror of such a radiation collector may have a EUV reflecting top layer of, for example, ruthenium (Ru). Deposition of more than approximately 10 nm tin (Sn) on the reflecting Ru layer may reflect EUV radiation in the same way as bulk Sn. The overall transmission of the collector would decrease significantly, since the reflection coefficient of tin is much lower than the reflection coefficient of ruthenium.

In order to prevent debris from the source or secondary particles generated by this debris from depositing on an optical element, a contaminant barrier may be used. Though such a contaminant barrier may remove part of the debris, some debris will still tend to deposit on the radiation collector or other optical elements.

### SUMMARY

It is an aspect of the present invention to provide a method for the protection of an optical element of a lithographic apparatus. It is an aspect of the invention to provide a device manufacturing method, wherein the optical element of the lithographic apparatus is protected according to the method for the protection.

According to an aspect of the invention, there is provided a method for the protection of an optical element of a lithographic apparatus, the optical element having a surface, the method comprising providing a deposition gas comprising SnH₄ to the surface of the optical element to deposit a Sn cap layer on the surface of the optical element.

Further, to that end, an aspect of the invention provides a device manufacturing method using a lithographic apparatus, wherein the lithographic apparatus comprises an optical element having a surface with a Sn cap layer. Both the method for the protection and the device manufacturing method are herein indicated as “method” and the term “method” refers herein to both the method for the protection and the device manufacturing method unless indicated otherwise or unless clear from the description.

In an embodiment, the Sn cap layer comprises at least 95 wt. % Sn, or at least 98 wt. % Sn, desirably before use of the lithographic apparatus. Other elements present in the cap layer may, in an embodiment, be selected from the group consisting of O, C and Si.

The method provides a protective cap layer to the optical element. Whereas Sn debris from a Sn source, assuming a lithographic apparatus uses a source of radiation based on a Sn plasma, may form domains on the surface of the optical element, the deliberately deposited Sn cap layer protects the optical element and diminishes optical deviances as a result of Sn debris deposition. SnH₄, when coming into contact with the surface of the optical element, spontaneously forms the Sn cap layer. Other hydrides (such as SiH₄) may, under the conditions of a lithographic apparatus, need thermal activation or other activation to decompose and result into a cap layer (such as a Si cap layer). SiH₄ typically decomposes at about 450° C. whereas SnH₄ typically already decomposes at about −50° C.

In an embodiment, the lithographic apparatus comprises a source of radiation constructed to generate EUV radiation wherein the source of radiation is a Sn plasma source. Herein, the term “constructed to generate EUV radiation” refers to sources which are designed to generate EUV radiation and which are designed to be used in EUV lithography. The source of radiation may comprise a laser produced plasma source (LPP) or a discharge produced plasma source (Sn plasma sources), respectively.

The cap layer has, in an embodiment, a mean layer thickness in the range of about 0.05-1.5 nm, of about 0.1-0.9 nm, or of about 0.3-0.6 nm. In an embodiment, the cap layer has a substantially uniform layer thickness, i.e. the deviation in layer thickness from the mean layer thickness are, in an embodiment, less than about 50% of the mean layer thickness, or not larger than about 0.2 or not larger than about 0.3 nm.

During lithographic processing, the cap layer may be damaged. For instance, debris from the source, such as Sn particles or agglomerates may impinge on the cap layer and may lead to a cap layer which is not smooth but which has defects (i.e. a non-uniform cap layer). Hence, in an embodiment, the method further comprises a repair process. This repair process may be applied after some running time of the lithographic apparatus, i.e. after using the lithographic apparatus some time for manufacturing devices, or in an embodiment during use of the lithographic apparatus. The repair process may be a partial or complete repair of the damaged cap layer.

In an embodiment, the method further comprises using the lithographic apparatus and subsequently exposing at least part of the cap layer to a repair gas comprising hydrogen radicals. Due to the presence of hydrogen radicals, Sn from the Sn cap layer can be redistributed, thereby at least partially repairing the damaged cap layer. It seems that SnH₄, which is formed by the exposure of the cap layer with the gas comprising hydrogen radicals forms Sn deposition at bare pieces of the optical element of the damaged cap layer. Due to this redistribution, a new or renewed cap layer is formed. In an embodiment, the damaged cap layer is exposed to the repair gas until the cap layer has a mean layer thickness selected from the range of 0.05-1 nm or 0.05-0.8 nm, is obtained.

In an embodiment, the method further comprises using the lithographic apparatus and subsequently exposing at least part of the cap layer to a repair gas comprising SnH₄. In this way, irregularities or even bare regions within the cap layer, may be filled with Sn, which is formed by decomposition of SnH₄ on the (damaged) cap layer. In an embodiment, the damaged cap layer is exposed to the repair gas (comprising SnH₄) until the cap layer has a mean layer thickness selected from the range of 0.05-1.5 nm.

In an embodiment, both hydrogen radicals and SnH₄ are comprised in the repair gas, i.e. the method further comprises using the lithographic apparatus and subsequently exposing at least part of the cap layer to a repair gas comprising SnH₄ and hydrogen radicals.

The cap layer may be damaged too much to be repaired, for instance with the above described repair processes with hydrogen radicals and/or SnH₄. Hence, in an embodiment, the (damaged) cap layer is at least almost completely removed and a “fresh” cap layer is deposited on the surface of the optical element. In an embodiment, the method further comprises using the lithographic apparatus and subsequently exposing at least part of the cap layer to a cleaning gas, removing at least part of the Sn cap layer by the cleaning gas, and providing the deposition gas comprising SnH₄ to the surface to deposit a fresh Sn cap layer on the surface of the optical element. In this way, a dynamic cap layer is provided, and a method is provided for the protection of the optical element, as well as a device manufacturing method, wherein the optical element is protected with a dynamic cap layer. The term “fresh cap layer” herein refers to a new cap layer that is provided after at least almost completely having removed a previous cap layer. In an embodiment, the term “subsequently” refers in an embodiment to “after some lithographic processing time” and refers in a specific embodiment to “after some lithographic processing time while still processing” (i.e. during use of the lithographic apparatus). In the latter embodiment, one or more of the processes of depositing, repairing and removing the cap layer are performed while processing with the lithographic apparatus.

In an embodiment, the cleaning gas may comprise a halogen, i.e. a gas comprising one or more halogens selected from the group consisting of F₂, Cl₂, Br₂ and I₂. These gases may remove almost the complete cap layer. Hence, in an embodiment, almost the complete Sn cap layer is removed by the cleaning gas. In an embodiment, the cleaning gas comprises I₂.

The optical element may be any optical element. In an embodiment, the optical element is a collector mirror, wherein the surface is a reflective surface of the collector mirror. The surface of the optical element is a surface that is designed to reflect, refract or transmit the radiation of the source (for which the source is constructed) e.g., to reflect, refract or transmit EUV radiation.

In principle, an embodiment of the method may be partially applied outside the apparatus. For instance, the cap layer may be generated ex situ from the lithographic apparatus, the cap layer may be repaired ex situ from the lithographic apparatus and/or the cap layer may be removed ex situ from the lithographic apparatus. However, in an embodiment, the process of providing the deposition gas comprising SnH₄ to the surface of the optical element to deposit the Sn cap layer on the surface of the optical element is an in situ lithographic apparatus process. In an embodiment, the process of exposing at least part of the cap layer to a repair gas is an in situ lithographic apparatus process. In an embodiment, the process of exposing at least part of the cap layer to a cleaning gas, removing at least part of the Sn cap layer by the cleaning gas, and optionally the process of further providing the deposition gas comprising SnH₄ to the surface to deposit a fresh Sn cap layer on the surface of the optical element is an in situ lithographic apparatus process. In an embodiment, one or more of the processes (including all (optional) processes) is performed in situ of the lithographic apparatus.

In a further aspect, a device manufacturing method is provided using a lithographic apparatus, wherein the lithographic apparatus comprises an optical element having a surface with a Sn cap layer (as described above). The optical element having the surface with the Sn cap layer is, in an embodiment, provided by providing a deposition gas comprising SnH₄ to the surface to deposit the Sn cap layer on the surface of the optical element in situ in the lithographic apparatus.

According to a further aspect, a lithographic apparatus is provided, the lithographic apparatus comprising an optical element, the optical element having a surface, the lithographic apparatus further comprising a gas source configured to supply a gas comprising SnH₄ and to direct a flow of the gas to the surface of the optical element and a cleaning gas source configured to supply a cleaning gas comprising a halogen and to direct a flow of cleaning gas to a Sn cap layer on the surface of the optical element. As mentioned above, the Sn cap layer is desirably a dynamic cap layer. The term “dynamic cap layer” refers to a Sn cap layer that may be removed, for instance after use of the lithographic apparatus, and may be formed again as fresh cap layer, for instance before a next use of the lithographic apparatus. The apparatus may further comprise a gas source configured to supply a gas comprising hydrogen radicals and may optionally comprise a Sn substrate. The Sn substrate is a substrate comprising Sn, such as a Sn layer, spatially separate from the optical element. The Sn substrate and the source of the gas comprising hydrogen radicals may be arranged to provide a flow of SnH₄ in the direction of the surface of the optical element. The hydrogen radicals may react with the Sn substrate to form SnH₄.

In an embodiment, the lithographic apparatus comprises an illumination system configured to condition a radiation beam; a support constructed to support a patterning device, the patterning device configured to impart the radiation beam with a pattern in its cross-section to form a patterned radiation beam; a substrate table constructed to hold a substrate; and a projection system configured to project the patterned radiation beam onto a target portion of the substrate. In an embodiment, the lithographic apparatus is an EUV lithographic apparatus. The lithographic apparatus may comprise a source of radiation constructed to generate the radiation beam, which in an embodiment is an EUV radiation beam, and the source of radiation is constructed to generate EUV radiation.

### BRIEF DESCRIPTION OF THE DRAWINGS

Embodiments of the present invention will now be described, by way of example only, with reference to the accompanying schematic drawings in which corresponding reference symbols indicate corresponding parts, and in which:

FIG. 1 schematically depicts a lithographic apparatus according to an embodiment of the present invention;

FIG. 2 schematically depicts a side view of an EUV illumination system and projection optics of a lithographic projection apparatus according to an embodiment of FIG. 1;

FIG. 3 schematically depicts a processing scheme of the optical element;

FIG. 4 schematically depicts an embodiment of a part of the lithographic apparatus;

FIGS. 5a and 5b schematically depict an embodiment of the method of the invention; and

FIG. 5c schematically clarifies FIGS. 5a and 5b.

### DETAILED DESCRIPTION

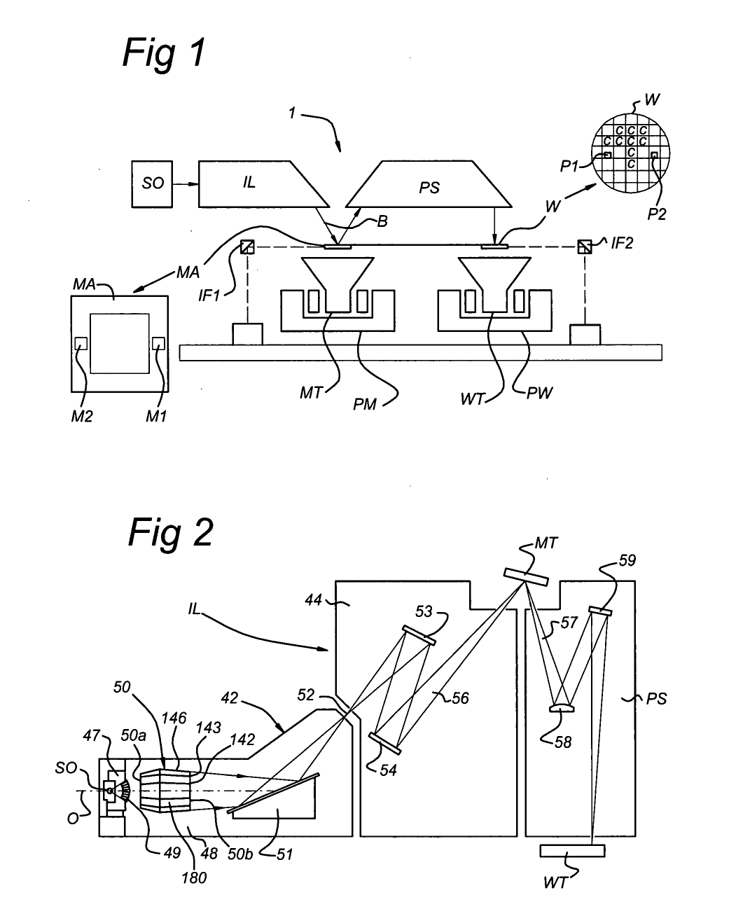

FIG. 1 schematically depicts a lithographic apparatus 1 according to an embodiment of the present invention. The apparatus 1 includes a source SO configured to generate radiation and an illumination system (illuminator) IL configured to condition a radiation beam B (e.g. UV radiation or EUV radiation) from the radiation received from source SO. The source SO may be provided as a separate unit and not be a part of the lithographic apparatus. A support (e.g. a mask table) MT is configured to support a patterning device (e.g. a mask) MA and is connected to a first positioning device PM configured to accurately position the patterning device MA in accordance with certain parameters. A substrate table (e.g. a wafer table) WT is configured to hold a substrate (e.g. a resist-coated wafer) W and is connected to a second positioning device PW configured to accurately position the substrate W in accordance with certain parameters. A projection system (e.g. a reflective projection mirror system) PS (also known as projection optics box POB) is configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, to direct, shape, or control radiation.

The support MT holds the patterning device in a manner that depends on the orientation of the patterning device, the design of the lithographic apparatus, and other conditions, such as for example whether or not the patterning device is held in a vacuum environment. The support MT can use mechanical, vacuum, electrostatic or other clamping techniques to hold the patterning device. The support MT may be a frame or a table, for example, which may be fixed or movable as required. The support MT may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a reflective type (e.g. employing a reflective mask). Alternatively, the apparatus may be of a transmissive type (e.g. employing a transmissive mask).

The lithographic apparatus may be of a type having two (dual stage) or more substrate tables (and/or two or more patterning device supports). In such “multiple stage” machines the additional tables and/or supports may be used in parallel, or preparatory steps may be carried out on one or more tables and/or supports while one or more other tables and/or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located, for example, between the projection system and the substrate during exposure.

Referring to FIG. 1, the illuminator IL receives radiation from a radiation source SO. The source and the lithographic apparatus may be separate entities, for example when the source is an excimer laser. In such cases, the source is not considered to form part of the lithographic apparatus and the radiation is passed from the source SO to the illuminator IL with the aid of a beam delivery system including, for example, suitable directing mirrors and/or a beam expander. In other cases the source may be an integral part of the lithographic apparatus, for example when the source is a mercury lamp.

The illuminator IL may include an adjusting device configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask) MA, which is held on the support (e.g., mask table) MT, and is patterned by the patterning device. Having traversed the patterning device MA, the radiation beam B passes through the projection system PS, which projects the beam onto a target portion C of the substrate W. With the aid of the second positioning device PW and position sensor IF2 (e.g. an interferometric device, linear encoder or capacitive sensor), the substrate table WT can be moved accurately, e.g. so as to position different target portions C in the path of the radiation beam B. Similarly, the first positioning device PM and another position sensor IF1 (e.g. an interferometric device, linear encoder or capacitive sensor) can be used to accurately position the patterning device MA with respect to the path of the radiation beam B, e.g. after mechanical retrieval from a mask library, or during a scan. In general, movement of the patterning device support MT may be realized with the aid of a long-stroke module (coarse positioning) and a short-stroke module (fine positioning), which form part of the first positioning device PM. Similarly, movement of the substrate table WT may be realized using a long-stroke module and a short-stroke module, which form part of the second positioning device PW. In the case of a stepper, as opposed to a scanner, the patterning device support MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:
a. In step mode, the patterning device support MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.
b. In scan mode, the patterning device support MT and the substrate table WT are scanned synchronously while a pattern imparted to the radiation beam is projected onto a target portion C (i.e. a single dynamic exposure). The velocity and direction of the substrate table WT relative to the patterning device support MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
c. In another mode, the patterning device support MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

The term “lens”, where the context allows, may refer to any one or combination of various types of optical components, including refractive, reflective, magnetic, electromagnetic and electrostatic optical components.

The terms “radiation” and “beam” used herein encompass all types of electromagnetic radiation, including ultraviolet (UV) radiation (e.g. having a wavelength λ of 365, 248, 193, 157 or 126 nm) and extreme ultra-violet (EUV or soft X-ray) radiation (e.g. having a wavelength in the range of 5-20 nm, e.g. 13.5 nm or 6.6 nm), as well as particle beams, such as ion beams or electron beams. Generally, radiation having wavelengths between about 780-3000 nm (or larger) is considered IR radiation. UV refers to radiation with wavelengths of approximately 100-400 nm. Within lithography, it is usually also applied to the wavelengths which can be produced by a mercury discharge lamp: G-line 436 nm; H-line 405 nm; and/or I-line 365 nm. VUV is Vacuum UV (i.e. UV absorbed by air) and refers to wavelengths of approximately 100-200 nm. DUV is Deep UV, and is usually used in lithography for the wavelengths produced by excimer lasers like 126 nm-248 nm. The person skilled in the art understands that radiation having a wavelength in the range of, for example, 5-20 nm relates to radiation with a certain wavelength band, of which at least part is in the range of 5-20 nm.

FIG. 2 shows the projection apparatus 1 in more detail, including a radiation system 42, an illumination system 44, and the projection system PS. The radiation system 42 includes the radiation source SO which may be a discharge plasma source. EUV radiation may be produced by a gas or vapor in the source, for example Xe gas, Li vapor or Sn vapor in which a very hot plasma is created to emit radiation in the EUV range of the electromagnetic spectrum. The very hot plasma is created by causing an at least partially ionized plasma by, for example, an electrical discharge. Partial pressures of, for example, 10 Pa of Xe, Li, Sn vapor or any other suitable gas or vapor may be required for efficient generation of the radiation. In an embodiment, a Sn source as EUV source is applied. The radiation emitted by radiation source SO is passed from a source chamber 47 into a collector chamber 48 via an optional contaminant barrier 49 which is positioned in or behind an opening in source chamber 47. The contaminant barrier 49 may comprise a channel structure. Contaminant barrier 49 may comprise a gas barrier or a combination of a gas barrier and a channel structure. The contaminant barrier 49 further indicated herein at least comprises a channel structure.

The collector chamber 48 includes a radiation collector 50 (herein also indicated as collector mirror) which may be formed by a grazing incidence collector. Radiation collector 50 has an upstream radiation collector side 50a and a downstream radiation collector side 50b. Radiation passed by collector 50 can be reflected off a grazing incidence mirror 51, for instance a grating spectral filter 51, to be focused in a virtual source point 52 at an aperture in the collector chamber 48. From collector chamber 48, a beam of radiation 56 is reflected in illumination system 44 via normal incidence reflectors 53, 54 onto a patterning device (e.g., a reticle or mask) positioned on patterning device support MT (e.g., a reticle or mask table). A patterned beam 57 is formed which is imaged in projection system PS via reflective elements 58, 59 onto substrate table WT. More elements than shown may generally be present in illumination system 44 and projection system PS. Grazing incidence mirror 51 may optionally be present, depending upon the type of lithographic apparatus. Further, there may be more mirrors present than those shown in the Figures, for example there may be 1-4 more reflective elements present than elements 58, 59.

Instead of or in addition to a grazing incidence mirror as collector mirror 50, a normal incidence collector may be applied. Collector mirror 50, as described herein in an embodiment in more detail as a nested collector with reflectors 142, 143, and 146, and as schematically depicted in, for example, FIG. 2, is herein further used as an example of a collector (or collector mirror). Hence, where applicable, collector mirror 50 as a grazing incidence collector may also be interpreted as collector in general and in a specific embodiment also as a normal incidence collector.

Instead of or in addition to a grating spectral filter 51, as schematically depicted in FIG. 2, a transmissive optical filter may be applied that is transmissive for EUV and less transmissive for or even substantially absorbing of UV radiation. In an embodiment, no filter 51 may be used at all. A “grating spectral filter” is herein further indicated as “spectral filter” which includes gratings or transmissive filters. Not depicted in schematic FIG. 2, but also included as an optional optical element may be an EUV transmissive optical filter, for instance arranged upstream of collector mirror 50, or an optical EUV transmissive filter in illumination system 44 and/or projection system PS.

The optical elements shown in FIG. 2 (and optical elements not shown in the schematic drawing of this embodiment) are vulnerable to deposition of contaminants (for instance, produced by source SO), for example, Sn. This is the case for the radiation collector 50 and, if present, the spectral filter 51. Hence, the cleaning method of an embodiment of the present invention may be applied to any of those optical elements, but also to any of the normal incidence reflectors 53, 54 and reflective elements 58, 59 or other optical elements, for example additional mirrors, gratings, etc. In an embodiment, the optical element is selected from the group consisting of collector mirror 50, radiation system 42, illumination system IL and projection system PS. In an embodiment, the element may also be a spectral filter 51. In an embodiment, the optical element is selected from the group consisting of one or more optical elements in radiation system 42 (like collector mirror 50—be it a normal incidence collector or grazing incidence collector), spectral filter 51 (grating or transmissive filter), radiation system (optical) sensor (not depicted), one or more optical elements in illumination system 44 (like mirrors 53 and 54 or other mirror, if present, and/or an illumination system (optical) sensor (not depicted)), and/or one or more optical elements in the projection system PS (like mirrors 58 and 59 or other mirror, if present, and/or a projection system (optical) sensor (not depicted)). In an embodiment, the element may be a mask (for instance indicated in FIG. 1 as mask MA), in particular a reflective multilayer mask. Therefore, the term optical element refers to one or more elements selected from the group consisting of a grating spectral filter, a transmissive optical filter, a multi-layer mirror, a coating filter on a multi-layer mirror, a grazing incidence mirror, a normal incidence mirror (such as a multi-layer collector), a grazing incidence collector, a normal incidence collector, a(n) (optical) sensor (such as an EUV sensitive sensor), and a mask.

Further, not only an optical element may be contaminated by deposition, such as Sn or contaminated by other material, but also construction elements such as walls, holders, supporting systems, gas locks, a contaminant barrier 49, etc. This deposition may not directly influence the optical properties of the optical elements, but due to re-deposition, this deposition may deposit (i.e. re-deposit) on optical elements, thereby influencing the optical properties. Hence, even deposition not deposited on optical elements may in a later stage due to re-deposition lead to contamination of surfaces of optical elements. This may lead to a decrease in optical performance like reflection, transmission, uniformity, etc.

In an embodiment (see also above), radiation collector 50 may be a grazing incidence collector. The collector 50 is aligned along an optical axis 0. The source SO or an image thereof is located on optical axis O. The radiation collector 50 may include reflectors 142, 143, 146 (also known as a Wolter-type reflector comprising several Wolter-type reflectors). These reflectors 142, 143, 146 may be nested and rotationally symmetric about optical axis O. In FIG. 2 (as well as in other Figures), an inner reflector is indicated by reference number 142, an intermediate reflector is indicated by reference number 143, and an outer reflector is indicated by reference number 146. The radiation collector 50 encloses a certain volume, i.e. the volume within the outer reflector(s) 146. Usually, this volume within outer reflector(s) 146 is peripherally closed, although small openings may be present. All the reflectors 142, 143 and 146 include surfaces of which at least part includes a reflective layer or a number of reflective layers. Hence, reflectors 142, 143 and 146 (more reflectors may be present and embodiments of radiation collectors 50 may have more than 3 reflectors), are at least partly designed for reflecting and collecting EUV radiation from source SO, and at least part of the reflector may not be designed to reflect and collect EUV radiation. For example, at least part of the back side of the reflectors may not be designed to reflect and collect EUV radiation. On the surface of these reflective layers, there may in addition be a cap layer for protection or an optical filter provided on at least part of the surface of the reflective layers.

The radiation collector 50 is usually placed in the vicinity of the source SO or an image of the source SO. Each reflector 142, 143, 146 may comprise at least two adjacent reflecting surfaces, the reflecting surfaces further from the source SO being placed at smaller angles to the optical axis O than the reflecting surface that is closer to the source SO. In this way, a grazing incidence collector 50 is configured to generate a beam of (E)UV radiation propagating along the optical axis O. At least two reflectors may be placed substantially coaxially and extend substantially rotationally symmetrically about the optical axis O. It should be appreciated that radiation collector 50 may have further features on the external surface of outer reflector 146 or further features around outer reflector 146, for example a protective holder, a heater, etc. Reference number 180 indicates a space between two reflectors, e.g. between reflectors 142 and 143.

During use, deposition may be found on one or more of the outer 146 and inner 142/143 reflector(s). The radiation collector 50 may be deteriorated by such deposition (deterioration by debris, e.g. ions, electrons, clusters, droplets, electrode corrosion from the source SO). Deposition of Sn, for example due to a Sn source, may, after a few mono-layers, be detrimental to reflection of the radiation collector 50 or other optical elements, which may necessitate the cleaning of such optical elements. Deposition due to a source of radiation, such as a discharge produced plasma source, may provide an uneven distribution of Sn on the surface of the optical element, which deteriorates the optical properties of such optical element.

According to an embodiment of the invention, there is provided a method for the protection of an optical element of a lithographic apparatus 1, the optical element having a surface, the method comprising providing a deposition gas comprising SnH₄ to the surface of the optical element to deposit a Sn cap layer on the surface of the optical element.

The term “layer” as used herein, as understood by those of ordinary skill in the art, may describe layers having one or more boundary surfaces with other layers and/or with other media such as vacuum in use. However, it should be understood that “layer” may also mean part of a structure. The term “layer” may also indicate a number of layers. These layers can be, for example, next to each other or on top of each other, etc. They may also include one material or a combination of materials. It should also be noted that the term “layers” used herein may particularly describe continuous layers; discontinuous layers are, for instance, cap layers that are damaged during processing. The term “deposition” herein refers to material that is chemically or physically attached to a surface (e.g. the surface of an optical element), as known to those of ordinary skill in the art.

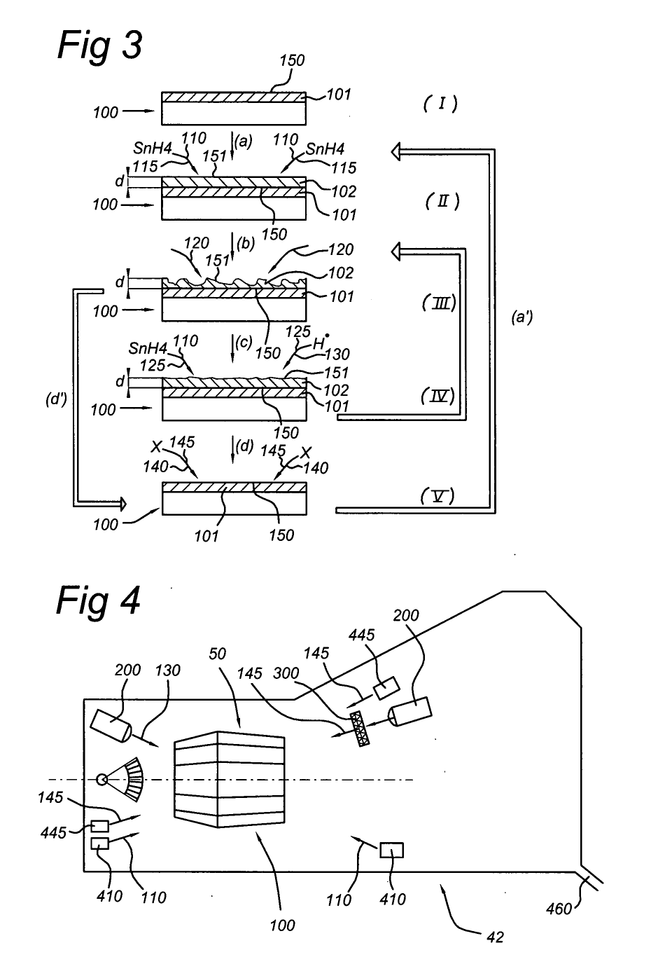

FIG. 3 schematically depicts an embodiment of the method of the invention including its (optional) processes. As mentioned above, the method may be a device manufacturing method using the lithographic apparatus 1. The optical element 100 may, in an embodiment, have a top layer 101, which may be, for example, a multi-layer, like a Mo—Si stack, or which may be a Ru top layer. Alternatively, it may be a protective layer, such as a Si₃N₄ layer. The surface of the optical element 100 is indicated with reference 150. This precapping stage is indicated with reference (I).

The optical element 100 is provided (in the lithographic apparatus) and is capped with a cap layer 102. To this end, a deposition gas 115 is introduced in the lithographic apparatus 1 and the surface 150 of the optical element 100 is exposed to this deposition gas 115. The deposition gas 115 comprises SnH₄. The deposition gas 115 may, in an embodiment, consist of one or more noble gases and SnH₄. SnH₄ is indicated with reference number 110. This process is indicated with reference (a). The surface of the cap layer 102 is indicated with reference 151. H₂ that is formed in this process and other gases may be exhausted from the lithographic apparatus. The Sn cap layer may comprise at least 95 wt. % Sn, or at least 98 wt. % Sn, desirably before use of the lithographic apparatus (see below). Other elements present in the cap layer may be, for instance, O, C and Si. In this way, deliberately a Sn cap layer 102 is provided on the surface 150 of the optical element. The cap layer 102 may have a mean layer thickness d in the range of 0.05-1.5 nm, or of about 0.1-0.9 nm. A lower layer thickness d of the cap layer 102 may include the risk of a non-uniform layer, i.e. a layer with a hole in it, thereby having the optical element 100 with bare surface (i.e. surface 150) regions within the cap layer 102, and a higher layer thickness d of the cap layer 102 may lead to a less desired loss of radiation during use of the lithographic process to make devices. The (mean) thickness d of the cap layer may be monitored by, for instance, reflectivity measurement (for a reflective optical element) or transparency (for a transmissive optical element) or other means known to the person skilled in the art, such as Raman spectroscopy, ellipsometry, or reflectometry. The capped optical element 100 after the deposition process (a) is now in stage (II) and is ready for use as optical element 100 in lithographic processing.

In an embodiment, the lithographic apparatus comprises a source of radiation SO constructed to generate EUV radiation wherein the source of radiation SO is a Sn plasma source.

During lithographic processing, the cap layer 102 may damage. For instance, debris from the source SO, such as Sn ions, particles or agglomerates may impinge on the cap layer 102 and may lead to a cap layer 102 which is not smooth but which has defects (i.e. a non-uniform cap layer 102). Ion etching may cause damage to the cap layer 102, which may be repaired because it may only remove part of the cap layer 102. Lithographic processing is schematically indicated with reference (b). After lithographic processing, also simply indicated as “after use” or “after use of the lithographic apparatus”, the optical element 100 is in stage (III). The damaged cap layer 102 is clearly shown in FIG. 3. Schematically, debris is indicated with reference 120.

Having reached stage (III), wherein the optical element 100 has a cap layer 102 with so many deficiencies that optimal lithographic processing may be impacted or not be possible anymore, the operator may choose two main routes, indicated as (c) or (d′). The route (c) can be indicated as a repair process, thereby arriving at stage (IV); route (d′) is chosen to remove the damaged cap layer 102 and after arriving at stage (V), wherein the cap layer 102 is at least partially removed, the process can continued by providing a fresh cap layer 102 via route (a′). The routes (c) and (d′) are described below.

In an embodiment, the method further comprises a repair process (route (c)). This process may be applied after some running time of the lithographic apparatus, i.e. after using the lithographic apparatus some time for manufacturing devices. The process may be a partial or complete repair of the damaged cap layer 102.

In an embodiment, the method further comprises using the lithographic apparatus 1 and subsequently exposing at least part of the cap layer 102 to a repair gas 125 comprising hydrogen radicals 130. Due to the presence of hydrogen radicals 130, the Sn from the Sn cap layer 102 can be redistributed, thereby at least partially repairing the damaged cap layer 102. SnH₄ 110, which is formed by the exposure of the cap layer 102 with the repair gas 125 comprising hydrogen radicals 130, desirably forms Sn deposition at bare pieces of the optical element 100 with damaged cap layer 102. Due to this redistribution, a new or renewed cap layer 102 is formed. In an embodiment, the damaged cap layer 102 is exposed to the repair gas 125 until a mean layer thickness d of 0.05-1 nm or 0.05-0.8 nm is obtained. In this way, the damaged cap layer 102 of stage (III) is repaired via this process (c) and stage (IV) is reached, wherein the cap layer 102 is at least partially repaired. The repair gas 125 may, in an embodiment, consist of one or more noble gases and hydrogen radicals. The H radical containing repair gas may typically comprise 0.0001-5% of H radicals, the rest being noble gas and H₂. A methods to generated hydrogen radicals 130 and sources (see also below) thereof are for instance described in United States patent application publication no. US 2006/0072084 and European patent application publication no. EP 1643310, which are incorporated herein in their entirety by reference.

In an embodiment, the method further comprises using the lithographic apparatus and subsequently exposing at least part of the cap layer 102 to the repair gas 125, wherein the repair gas comprises SnH₄. In this way, irregularities or even bare regions within the cap layer, may be filled with Sn, which is formed by decomposition of SnH₄ on the (damaged) cap layer. Also in this way, the damaged cap layer 102 of stage (III) is repaired via this process (c) and stage (IV) is reached, wherein the cap layer 102 is at least partially repaired. The repair gas 125 may thus, in an embodiment, consist of one or more noble gases and SnH₄, and may have the same composition as the deposition gas 115 described above. As mentioned above, the damaged cap layer may be exposed to the repair gas 125 comprising SnH₄ until the cap layer has (again) a mean layer thickness d in the range of 0.05-1.5 nm.

The embodiment of using H radicals and/or SnH₄ are schematically depicted in FIG. 3 (see right and left from arrow (c), respectively).

Therefore, an embodiment of the invention provides a method comprising:

a. a deposition process (a) comprising providing a deposition gas comprising SnH₄ to the surface of the optical element to deposit a Sn cap layer on the surface of the optical element;
b. use of the lithographic apparatus in a device manufacturing process (b);
c. optionally a repair process (c), wherein at least part of the cap layer after use of the lithographic apparatus is exposed to a repair gas comprising hydrogen radicals and/or SnH₄. Processes (b) and (c) may be repeated a plurality of times, i.e. after or during use the repair process (c) may be performed, and processing may be started again or continued, respectively. Since a laser produced plasma (LPP) EUV source produces mainly ionic debris, this method may be useful when the repair gas comprises SnH₄. For a lithographic apparatus comprising a LPP source, one may even no longer need the cleaning process (d) and (re)deposition process (a′) (discussed below) because one can keep on repeating to repair the layer, possibly even during operation of the lithographic apparatus.

Thus, lithographic processing (b) may be continued for some time. The sequence of processing (b) and repairing (c) may be continued until the quality of the repaired cap layer 102 is considered or is expected to be of such quality that that optimal lithographic processing may not be possible anymore. Hence, after stage (III) or after stage (IV), a more thorough cleaning may be applied, which are indicated as processes (d′) and (d), respectively. Hence, in an embodiment, the (damaged) cap layer 102 is substantially removed (stage (V)) and a “fresh” cap layer 102 is deposited on the surface 150 of the optical element 100 (i.e. process (a), as described above). Therefore, in an embodiment, the method further comprises using the lithographic apparatus 1 and subsequently exposing at least part of the cap layer 102 to a cleaning gas 145, removing at least part of the Sn cap layer 102 by the cleaning gas 145, and providing the deposition gas 115 comprising SnH₄ to the surface 150 to deposit a fresh Sn cap layer 102 on the surface 150 of the optical element 100.

The cleaning gas 145 may comprise one or more halogens 140, i.e. a gas comprising one or more halogens 140 selected from the group consisting of F₂, Cl₂, Br₂ and I₂ (schematically indicated in the figure as “X”). Such a gas 140 may substantially remove the complete cap layer 102. Hence, in an embodiment substantially the complete Sn cap layer 102 is removed by the cleaning gas 145. In an embodiment, the cleaning gas 145 comprises I₂.

In an embodiment, the method comprises:

a. a deposition process (a) comprising providing a deposition gas 115 comprising SnH₄ to the surface 150 of the optical element 100 to deposit a Sn cap layer 102 on the surface 150 of the optical element 100;
b. use of the lithographic apparatus 1 in a device manufacturing process (b);
c. optionally a repair process (c), wherein at least part of the cap layer 102 after use of the lithographic apparatus 1 is exposed to a repair gas 125 comprising hydrogen radicals and/or SnH₄;
d. a cleaning process (d), comprising exposing at least part of the cap layer 102 to a cleaning gas 145, removing at least part of the Sn cap layer 102 by the cleaning gas 145; and
e. a deposition process (a′) according to process (a).

Processes (b) and (c) may be repeated a plurality of times before performing processes (d) and (a′) (see also FIG. 3). This embodiment of the method may be useful for a lithographic apparatus equipped with a discharge produced plasma source, since such sources may tend to have a more detrimental impact on the cap layer 102 than a LPP source. However, this embodiment of the method may also be applied for a lithographic apparatus using a LPP source.

Note that the cleaning process (d) and the deposition process (a′) according to process (a), respectively, may be performed while using the lithographic apparatus in a device manufacturing method. However, as will be clear to the person skilled in the art, the deposition process (a′) (according to process (a)) to provide a fresh cap layer 102 will in general not be commenced before the Sn cap layer 102 has substantially been removed.

The process (a′) is indicated as (a′) in order to distinguish from the deposition process (a). The deposition process (a′) is herein also indicated as re-deposition process (or re-deposition process). The method comprises providing an Sn cap layer 102 on an optical element by providing SnH₄ to the optical element, thereby providing the cap layer 102. The cleaning (sub)process (d) and (re)deposition process (a′) are optional. However, as mentioned above, when the cap layer 102 is deteriorated, these processes may be performed.

The optical element 100 may be any optical element. In an embodiment, the optical element 100 is a collector mirror, such as schematically depicted in FIG. 2 and indicated with reference number 50, and wherein the surface 150 is a reflective surface of the collector mirror.

In principle, an embodiment of the method may be partially applied outside the lithographic apparatus 1. For instance, the cap layer 102 may be generated by process (a) ex situ from the lithographic apparatus 1, the cap layer 102 may be repaired by process (c)/(d′) ex situ from the lithographic apparatus 1 and the cap layer 102 may be removed by process (d) ex situ from the lithographic apparatus 1. However, in an embodiment, the process (a) of providing the deposition gas comprising SnH₄ (110) to the surface 150 of the optical element 100 to deposit the Sn cap layer 102 on the surface 150 of the optical element 102 is an in situ lithographic apparatus process. In an embodiment, the process (c) of exposing at least part of the cap layer 102 to the repair gas 125 is an in situ lithographic apparatus process. In an embodiment, the process (d) of exposing at least part of the cap layer 102 to the cleaning gas 145, removing at least part of the Sn cap layer 102 by the cleaning gas 145, and optionally also the process (a′) of further providing the deposition gas comprising SnH₄ 110 to the surface 150 to deposit a fresh Sn cap layer 102 on the surface 150 of the optical element 102 is an in situ lithographic apparatus process.

Note that repairing may also be performed during operation of the lithographic apparatus, i.e. the repair process (c) may be applied during or after lithographic processing (b), i.e. during or after the device manufacturing process (see also above).

As described above, in an aspect the invention, there is provided a device manufacturing method using a lithographic apparatus 1, such as schematically described herein as lithographic apparatus 1, wherein, in an embodiment, the lithographic apparatus 1 comprises optical element 100 having surface 150 with the Sn cap layer 102. The optical element 100 having the surface 150 with the Sn cap layer 102 is in an embodiment provided by providing a deposition gas 115 comprising SnH₄ (indicated with reference number 110) to the surface 150 to deposit the Sn cap layer 102 on the surface 150 of the optical element 100 in situ in the lithographic apparatus 1.

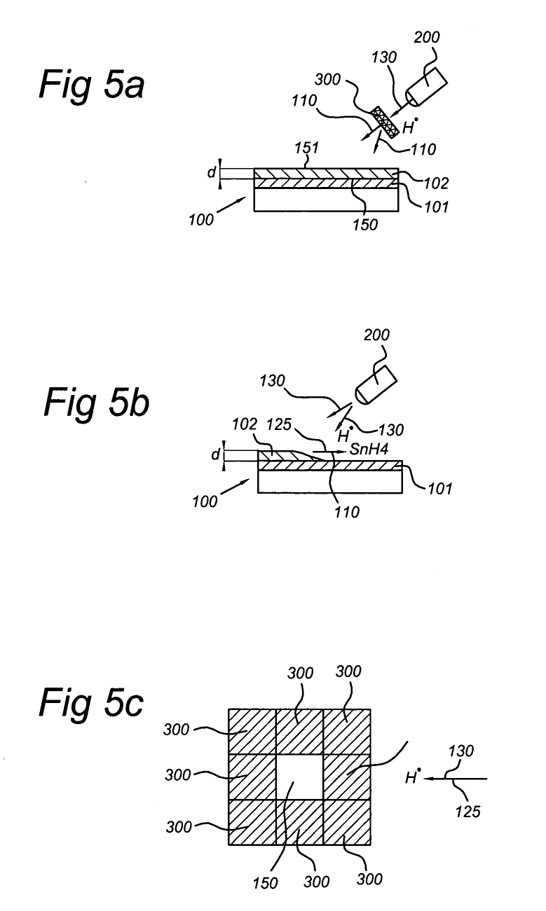

Referring to FIG. 4, an embodiment of part of the lithographic apparatus 1 is shown schematically, with a number of gas sources. The lithographic apparatus 1 comprises the optical element 100, the optical element 100 having surface 150, and further comprises a gas source 410 to supply a gas 110 comprising SnH₄ and to direct a flow of the gas 110 to the surface 150 of the of optical element 100. The lithographic apparatus 1 may also comprise a cleaning gas source 445 to supply a cleaning gas 145 comprising a halogen and to direct a flow of cleaning gas 445 to the Sn cap layer 102 (not shown in FIG. 5) on the surface 150 of the optical element 100 (in this case, the collector mirror 50 with reflectors 142, 143 and 146). The apparatus 1 (of which, by way of example, the radiation system 42 is shown) may comprise a gas source 200 configured to supply a gas 130 comprising hydrogen radicals and may optionally comprise a Sn substrate 300. The Sn substrate 300 and the source 200 may be arranged to provide a flow of SnH₄ 110 in the direction of the surface 150 of the optical element 100. The hydrogen radicals (130) may react with the Sn substrate 300 to form SnH₄ 110. In the absence of the substrate 300, the gas 130 comprising hydrogen radicals can be used as repair gas 125; in the presence of the substrate 300, the gas 130 comprising hydrogen radicals in combination with the Sn substrate 300 may be used to provide a flow of repair gas 125 comprising SnH₄ or alternatively, when the cap layer 102 has been removed, may be used to provide a flow of deposition gas 115. In the latter embodiment, i.e. the gas 130 comprising hydrogen radicals in combination with the Sn substrate 300 may be used to provide a flow of deposition gas 115, this combination can be used as the gas source 410 for the gas 110 comprising SnH₄ arranged. The gas source 410 may be used to provide the deposition gas 115 in process (a) and/or the repair gas 125 in process (c). Further, the lithographic apparatus 1 may comprise an exhaust 460 configured to remove gases and/or to facilitate the formation of gas flows, such as mentioned above.

FIGS. 5a and 5b schematically depict how the source 200 can be used to provide not only the repair gas 125 comprising hydrogen radicals (FIG. 5b), but also the repair gas 125 comprising SnH₄ when applied in combination with the Sn substrate 300 (FIG. 5a). As described above, the latter embodiment is substantially equal to the deposition gas 115. Hence, a source 200 of the gas 130 comprising hydrogen radicals in combination with a noble gas, such as Ar, and hydrogen may be applied as repair gas 125 or as deposition gas 115. The hydrogen radicals 130 react with the Sn substrate 300. The Sn substrate 300 can be wire, a mesh, or any object with an Sn surface. The substrate 300 may optionally be heated or be irradiated or be heated and be irradiated in order to improve SnH₄ formation. SnH₄, indicated as 110, may then provide the cap layer 102 to the surface 150 of optical element 100.

FIG. 5b schematically shows how this principle can be used to redistribute Sn on the surface 150 of the optical element 100, for instance after use of the lithographic apparatus 1.

FIG. 5b shows cap layer 102 non-uniformly distributed over the surface 150 of the optical element 100. Gas 130 comprising hydrogen radicals is generated by the hydrogen radical source 200. The hydrogen radicals react at a surface 151 of the cap layer 102 to form SnH₄ 110, which may then be used as repair gas 125. The repair gas 125 re-deposits Sn on the bare surface 150 of the optical element 100 to provide a substantially uniform cap layer 102 on the optical element 100, for instance with the above described mean layer thickness of about 0.05-1 nm. FIG. 5b therefore schematically depicts an embodiment of process (c). By redistribution of the Sn in the cap layer 102 over the surface 150 on the optical element 100, the damaged cap layer 102 after processing will be made more uniform, as schematically depicted in FIG. 3 (stage (IV)). In this embodiment, Sn on the optical element as cap layer 102 (or as deposition) acts at least partially as a Sn substrate.

Hence, a solution proposed here is to use a dynamic cap layer 102 of Sn. The Sn layer 102 is deposited using SnH₄ (110), and may be removed using a halogen cleaning (process (d)). Furthermore, if the protective Sn cap layer 102 has been partly sputtered away or otherwise deteriorated (during processing, process (b)), it may be restored by intermediately exposing the optical element 100 to SnH₄ again (i.e. an embodiment of the repair process (c)). This is possible because SnH₄ particularly decomposes on the surface 150, when this surface 150 is, for example, a Ru surface, leading to a restoration of the Sn cap layer 102 in the bare parts of the cap layer 102.

The EUV optics within EUV lithography system are often under the influence of ions and source-generated debris, especially if the EUV optics is located near the EUV source (e.g. an EUV collector). Typically, the EUV source uses Sn as fuel, and therefore normally the debris will comprise Sn. Ions can either be generated by the source, or they may be generated in a secondary EUV induced plasma. These ions may damage an EUV mirror by ion sputtering. Furthermore, source-generated debris may also deposit on the EUV optic, resulting in an EUV absorbing coating, which can be difficult to remove. A complicating effect may be that there are typically both sputter-dominated and deposition-dominated regions inside the EUV collector. Consequently, the protective coating protects against both ion sputtering and deposition, which is the case with an embodiment of the cap layer 102 described herein.

As mentioned above, if the EUV source substantially only induces ion sputtering damage to the Sn cap layer 102 (thus no deposition of particles), one may only need to use the repair process (c) and the cleaning process (d) followed by process (a′) may be skipped. In this case, the repair process is done using SnH₄ as repair gas to repair the Sn cap layer 102, since not enough Sn material may be available to do a “re-distributing repair process”. This is relevant for a LPP EUV source, which produces mainly ionic debris.

### Experiment

In order to find how much SnH₄ re-deposits on a Ru surface, hydrogen radicals were directed at a Ru surface surrounded by Sn-on-Si samples (see FIG. 5c, a schematic top view), wherein the Ru surface is indicated as bare surface 150, and wherein the Sn-on Si-samples are indicated as substrate 300. The table below shows the Sn coverage of the samples before and after this treatment as measured by XRF analysis:

| Samples | nm Sn |
|---|---|
| Sn-on-Si before | 5.4 |
| Sn-on-Si after | 0.04 |
| Ru before | <0.02 |
| Ru after | 4.1 |

From this table it can be seen that all Sn has been removed from the Sn-on-Si sample, whereas the amount of Sn on the Ru surface has increased. This demonstrates that SnH₄ particularly dissociates on a Ru surface. Furthermore, this demonstrates that Sn can indeed be moved from a Sn-coated part to a bare Ru surface, indicating that the smoothing or redistribution effect as described above may indeed occur.

Also, roughly 10% of the Sn removed from Sn samples was re-deposited on the Ru surface. Further, the principle of re-deposition works well on Ru surfaces. The remainder has been pumped away as gaseous SnH₄.

An embodiment of the invention thus provides a method for the protection of an optical element of a lithographic apparatus. A deposition gas comprising SnH₄ is provided to the surface of the optical element to deposit a Sn cap layer on the surface of the optical element. In this way, a Sn cap layer is deliberately provided on the optical element, which may protect the optical element during lithographic processing from debris from a (Sn) plasma source. During or after lithographic processing, the (deteriorated) cap layer may be repaired by providing a hydrogen radical containing gas and/or a SnH₄ containing gas. Additionally or alternatively, the (deteriorated) cap layer may be removed and a new (“fresh”) cap layer provided by providing the deposition gas comprising SnH₄.

Although specific reference may be made in this text to the use of lithographic apparatus in the manufacture of ICs, it should be appreciated that the lithographic apparatus described herein may have other applications, such as the manufacture of integrated optical systems, guidance and detection patterns for magnetic domain memories, flat-panel displays, flat panel displays including liquid-crystal displays (LCDs), thin-film magnetic heads, etc. It should be appreciated that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

While specific embodiments of the present invention have been described above, it should be appreciated that the present invention may be practiced otherwise than as described. For example, the present invention may take the form of a computer program containing one or more sequences of machine-readable instructions describing a method as disclosed above, or a data storage medium (e.g. semiconductor memory, magnetic or optical disk) having such a computer program stored therein. This computer program may be used to control the removal of the deposition, control the pressures, etc.

The descriptions above are intended to be illustrative, not limiting. Thus, it will be apparent to one skilled in the art that modifications may be made to the present invention as described without departing from the scope of the claims set out below. Use of the verb “to comprise” and its conjugations does not exclude the presence of elements or steps other than those stated in a claim. The article “a” or “an” preceding an element does not exclude the presence of a plurality of such elements.

The present invention is not limited to application of the lithographic apparatus or use in the lithographic apparatus as described in the embodiments. Further, the drawings usually only include the elements and features that are necessary to understand the present invention. Beyond that, the drawings of the lithographic apparatus are schematic and not on scale. The present invention is not limited to those elements, shown in the schematic drawings (e.g. the number of mirrors drawn in the schematic drawings). Further, the present invention is not confined to the lithographic apparatus described in relation to FIG. 1. The present invention described with respect to a radiation collector may also be employed to (other) multilayer, grazing incidence mirrors or other optical elements. It should be appreciated that embodiments described above may be combined.

What is claimed is:

1. A method for the protection of an optical element of a lithographic apparatus, the optical element having a surface, the method comprising providing a deposition gas comprising SnH₄ to the surface of the optical element to deposit a Sn cap layer on the surface of the optical element.

2. The method of claim 1, wherein the lithographic apparatus comprises a source of radiation constructed to generate EUV radiation, and wherein the source of radiation is a Sn plasma source.

3. The method of claim 1, wherein the cap layer has a mean layer thickness in the range of 0.05-1.5 nm.

4. The method of claim 1, further comprising using the lithographic apparatus and subsequently exposing at least part of the cap layer to a repair gas comprising hydrogen radicals.

5. The method of claim 4, wherein the Sn cap layer is exposed to the repair gas until the cap layer has a mean layer thickness selected from the range of 0.05-1 nm.

6. The method of claim 1, further comprising using the lithographic apparatus and subsequently exposing at least part of the cap layer to a repair gas comprising SnH₄.

7. The method of claim 6, wherein the Sn cap layer is exposed to the repair gas until the cap layer has a mean layer thickness selected from the range of 0.05-1.5 nm.

8. The method of claim 1, further comprising using the lithographic apparatus and subsequently exposing at least part of the cap layer to a cleaning gas, removing at least part of the Sn cap layer using the cleaning gas, and providing the deposition gas comprising SnH₄ to the surface to deposit a fresh Sn cap layer on the surface of the optical element.

9. The method of claim 8, wherein substantially the complete Sn cap layer is removed by the cleaning gas and wherein the cleaning gas comprises a halogen.

10. The method of claim 1, wherein the Sn cap layer comprises at least 95 wt. % Sn.

11. The method of claim 1, wherein the optical element is a collector mirror and wherein the surface is a reflective surface of the collector mirror.

12. The method of claim 1, wherein providing the deposition gas comprising SnH₄ to the surface of the optical element to deposit the Sn cap layer on the surface of the optical element is an in situ lithographic apparatus process.

13. The method of claim 1, comprising
a. use of the lithographic apparatus in a device manufacturing process (a);
b. a repair process (b), wherein at least part of the cap layer after use of the lithographic apparatus is exposed to a repair gas comprising hydrogen radicals or SnH₄;
wherein processes (a) and (b) are repeated a plurality of times.

14. The method of claim 1, comprising
a. use of the lithographic apparatus in a device manufacturing process (a);
b. a repair process (b), wherein at least part of the cap layer after use of the lithographic apparatus is exposed to a repair gas comprising hydrogen radicals or SnH₄;
c. a cleaning process (c), comprising exposing at least part of the cap layer to a cleaning gas, removing at least part of the Sn cap layer by the cleaning gas; and
d. after cleaning process (c), a deposition process (d) comprising providing a deposition gas comprising SnH₄ to the surface of the optical element to deposit a fresh Sn cap layer on the surface of the optical element;
wherein processes (a) and (b) are repeated a plurality of times before performing processes (c) and (d).

15. A lithographic apparatus comprising an optical element, the optical element having a surface, a gas source configured to supply a gas comprising SnH₄ and to direct a flow of the gas to the surface the of optical element and a cleaning gas source configured to supply a cleaning gas comprising a halogen and to direct a flow of cleaning gas to a Sn cap layer on the surface of the optical element.

16. The lithographic apparatus of claim 15, wherein the Sn cap layer is a dynamic cap layer.

17. A device manufacturing method using a lithographic apparatus, wherein the lithographic apparatus comprises an optical element having a surface with a Sn cap layer.

18. The device manufacturing method of claim 17, further comprising using the lithographic apparatus and subsequently exposing at least part of the cap layer to a repair gas comprising hydrogen radicals.

19. The device manufacturing method of claim 17, further comprising using the lithographic apparatus and subsequently exposing at least part of the cap layer to a repair gas comprising SnH₄.

20. The device manufacturing method of claim 17, further comprising using the lithographic apparatus and subsequently exposing at least part of the cap layer to a cleaning gas, removing at least part of the Sn cap layer using the cleaning gas, and providing a deposition gas comprising SnH₄ to the surface to deposit a fresh Sn cap layer on the surface of the optical element.

21. The device manufacturing method of claim 17, wherein the Sn cap layer is provided by providing a deposition gas comprising SnH₄ to the surface to deposit the Sn cap layer on the surface of the optical element in situ in the lithographic apparatus.

22. The device manufacturing method of claim 17, wherein the optical element is a collector mirror and wherein the surface is a reflective surface of the collector mirror.
